(19) United States
(12) Patent Application Publication
(10) Pub. No.: US 2002/0008301 A1
(43) Pub. Date: Jan. 24, 2002

(54) MONOLITHIC HIGH-Q INDUCTANCE DEVICE AND PROCESS FOR FABRICATING THE SAME

(76) Inventors: PING LIOU, HSINCHU (TW); HAO-CHIEN YUNG, HSINCHU (TW); SHING SHING SHIANG, HSINCHU HSIEN (TW)

Correspondence Address: RICHARD P BERG, LSDAS & PARRY, 5670 WILSHIRE BOULEVARD, SUITE 2100, LOS ANGELES, CA, 900365679

(21) Appl. No.: 09/212,319

(22) Filed: Dec. 15, 1998

(30) Foreign Application Priority Data
Jul. 13, 1998 (TW) 87111340

(51) Int. Cl. H01L 29/00

(52) U.S. Cl. 257/531

(57) ABSTRACT

The present invention provides a high-Q inductance device and a process for fabricating the same. The inductance device is formed on a semiconductor substrate and includes a first insulating layer, a second insulating layer, and a conducting coil. The first and second insulating layers are covered on different surfaces of the semiconductor substrate, respectively, and the second insulating layer has a lower dielectric constant than the first insulating layer. The conducting coil is formed on the second insulating layer. According to the present invention, the parasitic capacitance between the conducting coil and the substrate can be decreased by means of forming a conducting coil on an insulating layer having a low dielectric constant.

### BACKGROUND OF THE INVENTION

1. Field of the Invention

The present invention relates to a process for fabricating semiconductor devices, and more particularly to a monolithic high-Q inductance device and a process for fabricating the same. The process involves forming a conducting coil on an insulating layer having a low dielectric constant, so as to decrease the parasitic capacitance effect.

2. Description of the Prior Art

Miniaturization of electronic circuits is a goal in virtually every field, not only to achieve compactness in mechanical packaging, but also to decrease the cost of manufacture of the circuits. Many digital and analog circuits, including high-capacity memory devices, high-level microprocessors and operational amplifiers, have been successfully implemented in silicon based integrated circuits (ICs). These circuits typically include active devices such as bipolar junction transistors (BJTs) and field effect transistors (FETs), diodes of various types, and passive devices such as resistors and capacitors.

One area that remains a challenge to miniaturize is radio frequency (RF) circuits, such as those used in cellular telephones, wireless modems, and other types of communication equipment. The problem is the difficulty in producing a good inductor in silicon technologies that is suitable for RF applications. Attempts to integrate inductors into silicon technologies have yielded either inductors of low quality factor (hereinafter, Q value) and high loss, or required special metalization layers such as gold.

Ewen et al. in U.S. Pat. No. 5,446,311 has disclosed a process for manufacturing high-Q inductors without using a noble metal such as gold. The process involves forming multiple metal layers with identical spiral patterns stacked up on an insulating layer to construct an inductance device. Such multiple metal layers can decrease series resistance, thus increasing the Q value. The lump-sum equivalent circuit is as shown in FIG. 1. In FIG. 1, C_{d} indicates the parasitic capacitance between the metal layers, L is the inductance, Rₛ is the series resistance of the spiral metal levels, and C₁ and C₂ are the parasitic capacitance between the substrate and the metal layers. If the semiconductor substrate is made of a lossy material such as silicon, then R₁ and R₂ indicate the parasitic resistances connected in parallel with C₁ and C₂, respectively. In addition, since the semiconductor substrate is usually grounded, R₁, R₂, C₁, and C₂ are grounded at one end.

In semiconductor techniques, silicon oxide (SiOₓ) is the most common insulating material, which has a relatively high dielectric constant (or relative permittivity) between 3.9 and 4.5. Since the resonant frequency is inversely proportional to C^{-½} and the capacitance (C) is proportional to the dielectric constant, when the dielectric constant increases, the self-resonance frequency decreases. Therefore, in U.S. Pat. No. 5,446,311, though the Q value is increased by the multiple metal layers, because of the high dielectric constant of the silicon oxide, the self-resonant frequency of the inductance device is decreased, thus limiting the application of the inductance device on high frequency.

Abidi et al. in U.S. Pat. No. 5,539,241 have disclosed an inductor which is formed in an oxide layer overlying a silicon substrate in which the silicon material underneath the inductor is selectively removed to form a pit so as to space the inductor from the underlying silicon substrate. In the illustrated embodiment, the silicon beneath the inductor is removed by etching, leaving the inductor suspended on the oxide layer overlying the substrate. The pit beneath the inductor is filled with an insulating medium such as air so that the parasitic capacitance of the inductor is substantially reduced and yet retains a relatively large self-resonant frequency on the order of 2 GHz or more. However, the etching of the substrate makes the whole process more complicated and incompatible with BiCMOS or CMOS standard processes.

### SUMMARY OF THE INVENTION

Therefore, an object of the present invention is to solve the above-mentioned problems and to provide an inductance device with high-Q and to provide a process for fabricating the inductance device. The process involves forming a conducting coil on an insulating layer of a relatively low dielectric constant, so as to decrease the parasitic capacitance effect.

Another object of the present invention is to provide an inductance device with high-Q and to provide a process for fabricating the inductance device, in which the process is compatible with the BiCMOS and CMOS standard processes.

The above objects of the present invention can be achieved by providing a high-Q inductance device. The inductance device of the present invention is formed on a semiconductor substrate, and includes a first insulating layer, a second insulating layer, and a conducting coil. The first insulating layer and the second insulating layer are covered on different surfaces of the semiconductor substrate respectively, and the second insulating layer has a lower dielectric constant than the first insulating layer. The conducting coil is formed on the second insulating layer.

In addition, the present invention also provides a process for fabricating an inductance device. A first insulating layer and a second insulating layer are formed on different surfaces of a semiconductor substrate, respectively. The second insulating layer has a lower dielectric constant than the first insulating layer. Then, a conducting coil is formed on the second insulating layer.

According to the present invention, since the conducting coil is formed on the insulting layer with a relatively-low dielectric constant, the parasitic capacitance between the conducing coil and the substrate can be decreased.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1 shows the lump-sum equivalent circuit of a conventional inductance device.

FIG. 2 is a top view of an inductance device according to the present invention.

FIG. 3 is a cross-sectional view taken along the line III-III of FIG. 2 according to an embodiment.

FIG. 4 is a cross-sectional view taken along the line III-III of FIG. 2 according to another embodiment.

FIGS. 5A-5C are cross-sectional views, illustrating the process flow of forming the second insulating layer according to a first preferred embodiment.

FIGS. 6A-6C are cross-sectional views, illustrating the process flow of forming the second insulating layer according to a second preferred embodiment.

FIGS. 7A-7C are cross-sectional views, illustrating the process flow of forming the second insulating layer according to a third preferred embodiment.

### DETAILED DESCRIPTION OF THE PREFERRED EMBODIMENTS

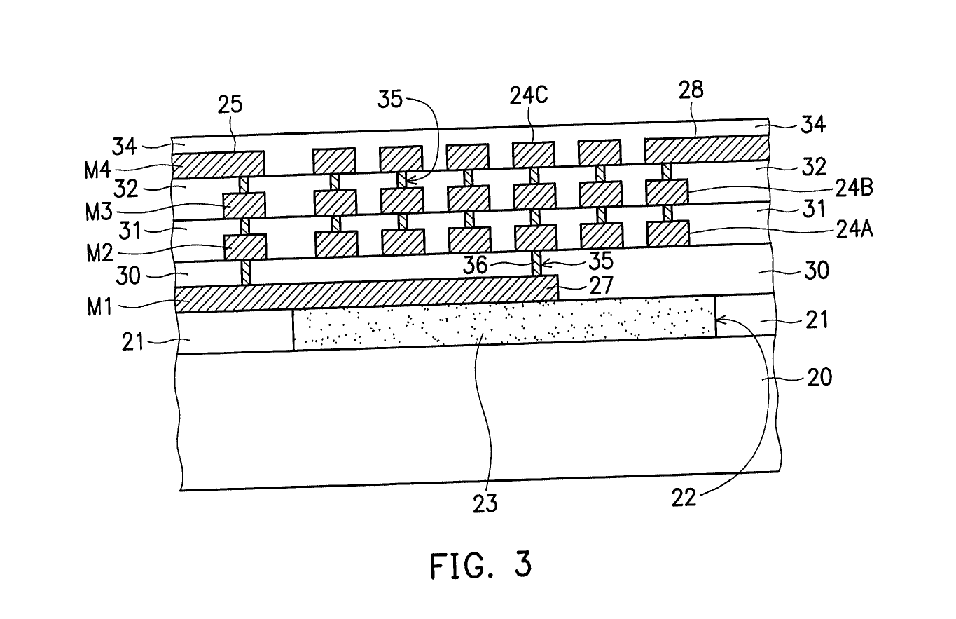

Refer to FIGS. 2 and 3, showing an inductance device according to the present invention, in which FIG. 2 is the top view, and FIG. 3 is a cross-sectional view taken along the line III-III of FIG. 2. In the figures, a semiconductor substrate 20 is a silicon substrate, on which some semiconductor devices such as bipolar junction transistors or field effect transistors have been formed but are not shown. A first insulating layer 21 is formed over the whole surface of the semiconductor substrate 20. The first insulating layer 21 is usually made of silicon oxide. A portion of the first insulating layer 21, over which a spiral conducting coil 24 will be formed, is removed by photolithography and etching to expose the semiconductor substrate 20 and form a trench 22. If the first insulating layer 21 is made of silicon oxide, such etching can be employed by reactive ion etching (RIE) or high density plasma etching (HDP), using a mixed gas including CF₄ and/or CHF₃ as the etching gas and argon as the carrier gas.

Then, a second insulating layer 23 is filled into the trench 22. According to the present invention, the second insulating layer 23 has a lower dielectric constant than the first insulating layer 21. The second insulating layer 23 can be formed by spin coating a polymer. Such a polymer can be a polyimide having a dielectric constant between 3.0 and 3.7, a polysilsequioxane having a dielectric constant between 2.7 and 3.0, an F-doped polyimide having a dielectric constant of about 2.5, an organic SOG having a dielectric constant between 2.0 and 3.0, an F-doped TEOS having a dielectric constant between 3.0 and 3.5, and other similar silicon or carbon based organic polymer films.

Subsequently, a spiral conducting coil 24 is formed over the second insulating layer 23. For the purpose of example, the spiral conducting coil 24 shown in FIG. 2 has three turns. Those who are skilled in the art can adjust the coil turns according to the desired inductance value. Therefore, the turns shown in FIG. 2 are not used to limit the present invention. The spiral conducting coil 24 can be formed by physical vapor deposition (PVD), photolithography, and anisotropic etching to define the patterns of the spiral conducting coil 24. For the convenience of measuring, pads 25 and 26 are formed to connect the probe; thus, one end of the spiral conducting coil 24 is coupled to the pad 25 through a wiring 27, and the other end is connected to the pad 26 through another wiring 28. The wiring 27 shown in FIG. 2 is located beneath the spiral conducting coil 24; therefore, it is indicated by a dash line.

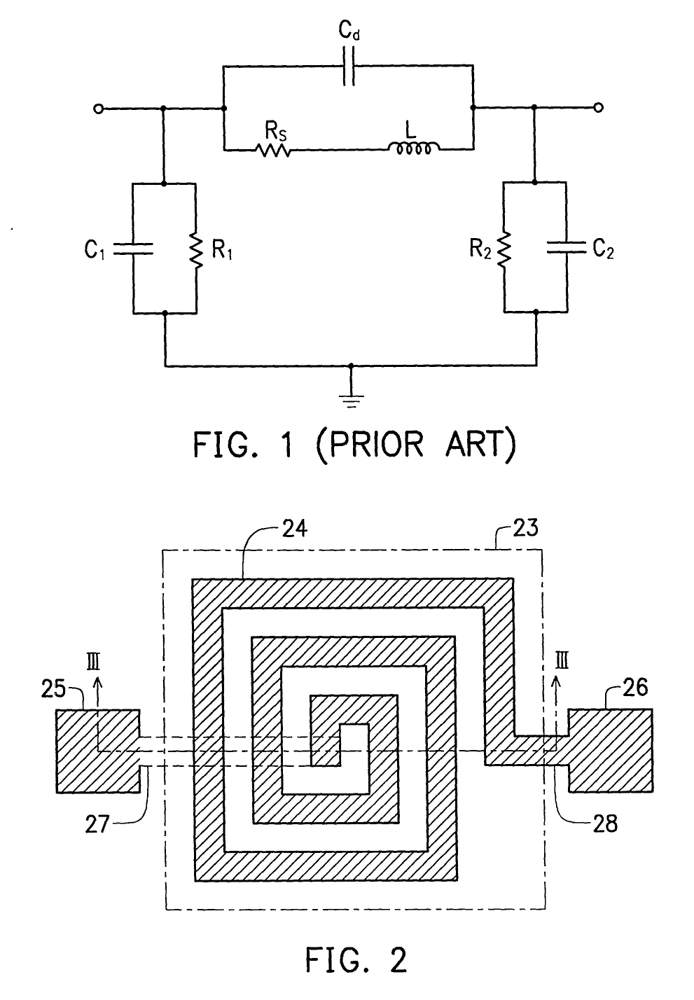

In order to reduce the serial resistance Rₛ shown in FIG. 1, the spiral conducting coil 24 can be in a structure of multiple metal layers as shown in FIG. 3.

Referring to FIG. 3, after the second insulating layer 23 is filled into the trench 22, etching back or chemical mechanical polishing (CMP) technology can be performed to obtain a flat surface. Then, a first conducting layer M1 is deposited and patterned. The first conducting layer M1 is preferably made of an aluminum-copper alloy, under which a barrier layer (not shown) made of titanium or titanium nitride is optionally formed to prevent aluminum from penetrating into the silicon substrate 20. The first conducting layer M1 can be formed, for example, by physical vapor deposition (PVD). Then, photolithography and anisotropic etching are performed to define the pattern of the wiring 27. Such anisotropic etching can be performed by reactive ion etching (RIE) or by high density plasma etching (HDP) in the presence of a mixed gas including a chlorine-containing reactant.

Subsequently, a first inter-metal dielectric layer 30 is deposited over the whole surface and is etched to define via holes 35. A second conducting layer M2 is deposited and patterned to form a first spiral conducting line 24A. The second conducting layer M2 can be made of an aluminum-copper alloy deposited by physical vapor deposition, and is directly filled into the via holes 35, through which the second conducting layer M2 is electrically connected to the wiring 27. In addition, metal plugs 36 made of tungsten can be filled into the via holes 35 before the formation of the second conducting layer M2. In FIG. 3, the first spiral conducting line 24A is electrically connected to the wiring 27 through the respective metal plugs 26.

Subsequently, a second inter-metal dielectric layer 31 is deposited over the whole surface and is etched to define via holes 35. A third conducting layer M3 is deposited and patterned to form a second spiral conducting line 24B. The third conducting layer M3 can be made of an aluminum-copper alloy deposited by physical vapor deposition, and is directly filled into the via holes 35, through which the third conducting layer M3 is electrically connected to the first spiral conducting line 24A. Alternatively, the second spiral conducting line 24B can be electrically connected to the first spiral conducting line 24A through the respective metal plugs 26 as shown in FIG. 3.

Subsequently, according to the process mentioned above, a third inter-metal dielectric layer 32 is deposited over the whole surface and is etched to define via holes 35. A fourth conducting layer M4 is deposited and patterned to form a third spiral conducting line 24C. The fourth conducting layer M4 can be made of an aluminum-copper alloy deposited by physical vapor deposition and is directly filled into the via holes 35, through which the fourth conducting layer M4 is electrically connected to the second spiral conducting line 24B. Alternatively, the third spiral conducting line 24C can be electrically connected to the second spiral conducting line 24B through the respective metal plugs 26 as shown in FIG. 3. Simultaneously, the fourth conducting layer M4 is patterned to form pads 25 and 26, and the wiring 28. The wiring 27 is electrically connected to the pad 25 through the patterned first conducting layer M1, the second conducting layer M2, and the third conducting layer M3.

Finally, a passivation layer 24 is deposited over the whole surface, which can be made of silicon oxide or silicon nitride.

From FIG. 3, it is known that the first spiral conducting line 24A, the second spiral conducting line 24B, and the third spiral conducting line 24C construct the spiral conducting coil 24 in FIG. 2. The adjacent spiral conducting lines, such as lines 24A and 24B, and lines 24B and 24C, are electrically connected to each other by at least one metal plug 36. By the multiple conducting layers of the present invention, the serial resistance Rₛ can be substantively decreased. Since the Q value is inversely proportional to the serial resistance Rₛ, the Q value of the inductance device can be increased accordingly. In addition, the first spiral conducting line 24A, the second spiral conducting line 24B, and the third spiral conducting line 24C are all located over the second insulating layer 23, which has a relatively low dielectric constant; therefore, the parasitic capacitance C₁ and C₂ between the substrate and the conducting layers can be decreased, thus increasing the self-resonant frequency of the inductance device.

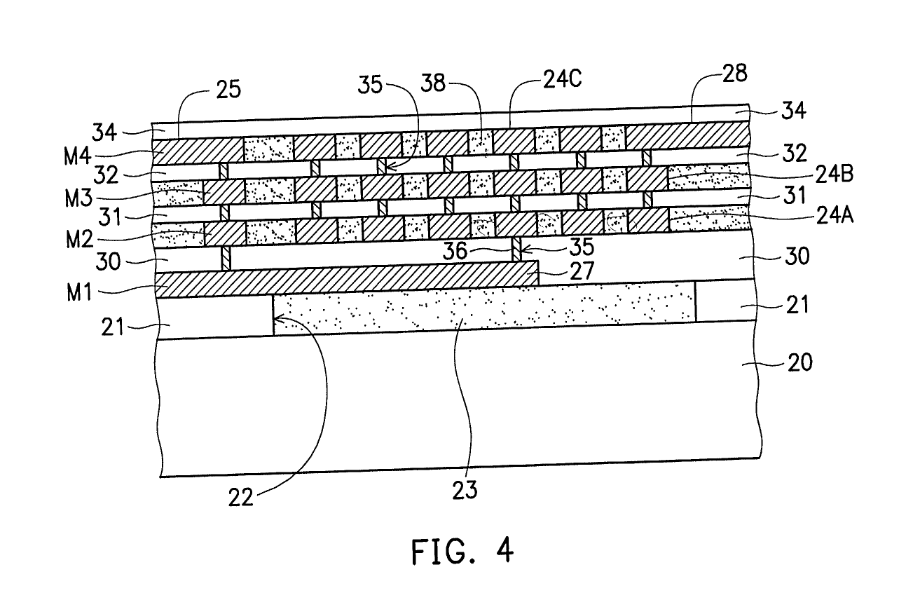

FIG. 4 is a cross-sectional view taken along the line III-III of FIG. 2 according to another embodiment. FIG. 4 differs from FIG. 3 in that before the formation of the second inter-metal dielectric layer 31, the third inter-metal dielectric layer 32, and the passivation layer 34, a material 38 having a relatively-low dielectric constant is filled into the space around the first spiral conducting line 24A, the space around the second spiral conducting line 24B, and the space around the third spiral conducting line 24C. Thus, the parasitic capacitance C_{d} between the lines as shown in FIG. 1 will be decreased. The material 38 having a low dielectric constant can be obtained by spin coating a polymer. Such a polymer can be a polyimide having a dielectric constant between 3.0 and 3.7, a polysilsequioxane having a dielectric constant between 2.7 and 3.0, an F-doped polyimide having a dielectric constant of about 2.5, an organic SOG having a dielectric constant between 2.0 and 3.0, an F-doped TEOS having a dielectric constant between 3.0 and 3.5, and other similar silicon or carbon based organic polymer films.

For example, if the first insulating layer 21 includes an undoped TEOS layer, a BPSG layer, and a plasma-enhanced deposited TEOS layer (PETEOS), the second insulating layer 23 having a low dielectric constant can be formed by various ways, three kinds of which are described as follows.

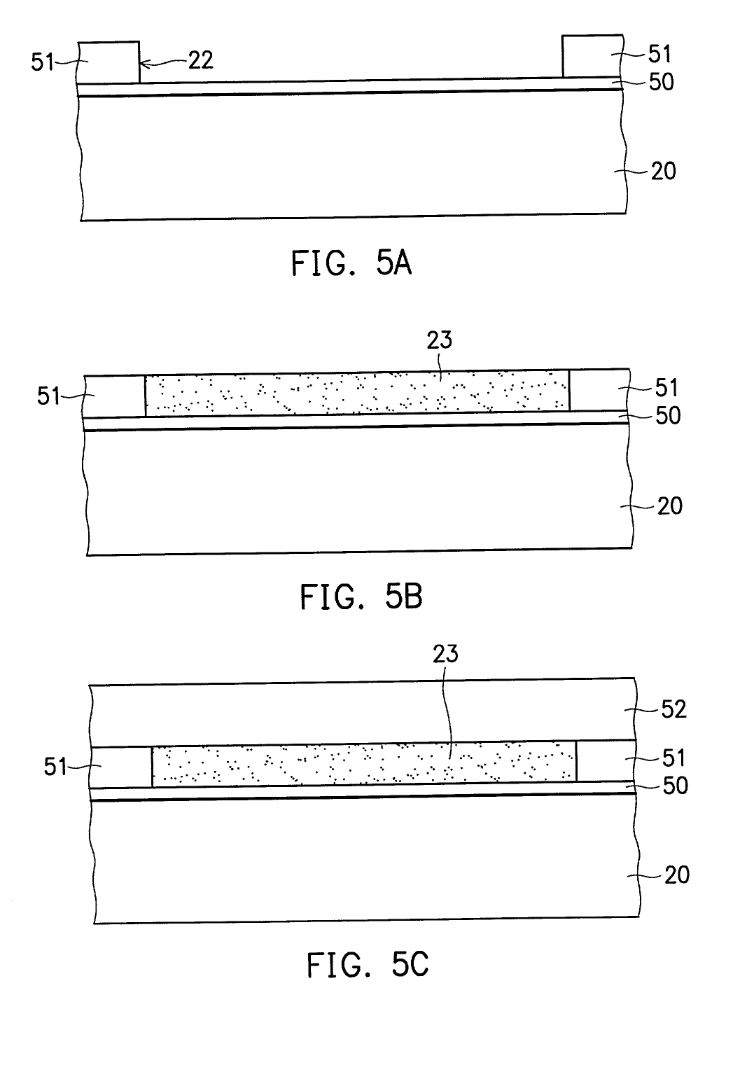

FIGS. 5A-5C are cross-sectional views, illustrating the process flow of forming the second insulating layer 23 according to a first preferred embodiment. Referring to FIG. 5A, an undoped TEOS layer 50 and a BPSG layer 51 are formed over the whole surface of the semiconductor substrate 20 in sequence. A portion of the BPSG layer 51, over which a spiral conducting coil 24 will be formed, is removed by photolithography and etching to expose the undoped TEOS layer 50 and form a trench 22. Then, a second insulating layer 23 is filled into the trench 22 and is planarized by etching back or chemical mechanical polishing to obtain a structure as shown in FIG. 5B. A PETEOS layer 52 is then formed on the second insulating layer 23 and the BPSG layer 51 to obtain a structure as shown in FIG. 5C.

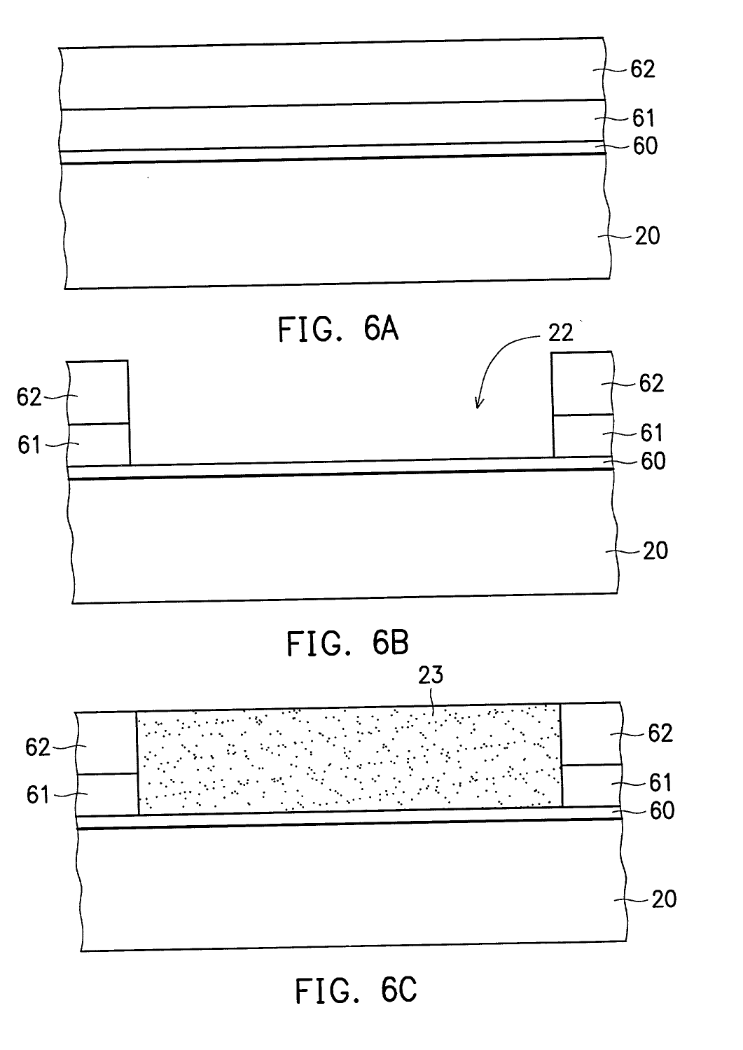

FIGS. 6A-6C are cross-sectional views illustrating the process flow of forming the second insulating layer 23 according to a second preferred embodiment. Referring to FIG. 6A, an undoped TEOS layer 60, a BPSG layer 61, and a PETEOS layer 62 are formed over the whole surface of the semiconductor substrate 20 in sequence. A portion of the BPSG layer 61 and a portion of the PETEOS layer 62, over which a spiral conducting coil 24 will be formed, are removed by photolithography and etching to expose the undoped TEOS layer 60 and form a trench 22, as shown in FIG. 6B. Then, a second insulating layer 23 is filled into the trench 22 and is planarized by etching back or chemical mechanical polishing to obtain a structure as shown in FIG. 6C.

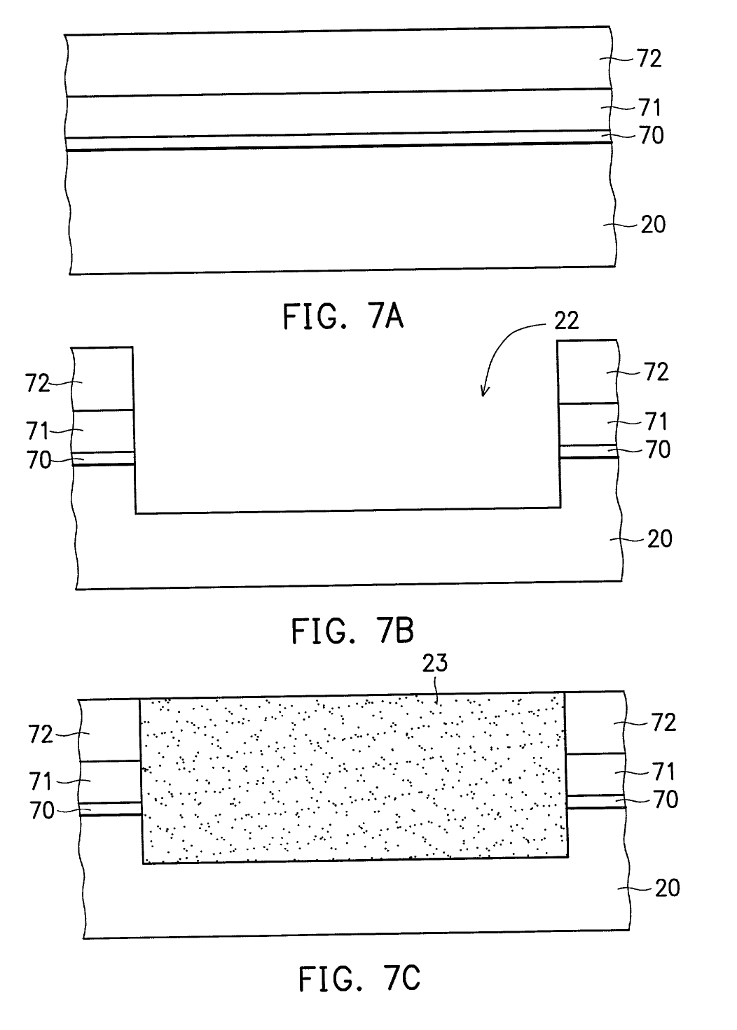

FIGS. 7A-7C are cross-sectional views illustrating the process flow of forming the second insulating layer 23 according to a third preferred embodiment. Referring to FIG. 7A, an undoped TEOS layer 70, a BPSG layer 71, and a PETEOS layer 72 are formed over the whole surface of the semiconductor substrate 20 in sequence. A portion of the undoped TEOS layer 70, a portion of the BPSG layer 71, and a portion of the PETEOS layer 72, over which a spiral conducting coil 24 will be formed, are removed by photolithography and etching to penetrate part of the semiconductor substrate 20 and form a trench 22, as shown in FIG. 7B. Then, a second insulating layer 23 is filled into the trench 22, as shown in FIG. 7C.

Since the capacitance is inversely proportional to the thickness, the parasitic capacitance C₁ and C₂ of the conducting coil 24 in FIG. 6C is lower than that in FIG. 5C, and the parasitic capacitance C₁ and C₂ of the conducting coil 24 in FIG. 7C is lower than that in FIG. 6C.

The foregoing description of the preferred embodiments of the present invention has been provided for the purpose of illustration and description. It is not intended to be exhaustive or to limit the invention to the precise forms disclosed. Many modifications and variations will be apparent to practitioners skilled in the art. The embodiments were chosen and described to best explain the principles of the invention and its practical application, thereby enabling others skilled in the art to under stand the invention to practice various other embodiments and make various modifications suited to the particular use contemplated. It is intended that the scope of the invention be defined by the following claims and their equivalents.

What is claimed is:

1. An inductance device formed on a semiconductor substrate, comprising:
a first insulating layer and a second insulating layer, which are covered on different surfaces of the semiconductor substrate respectively, the second insulating layer having a lower dielectric constant than the first insulating layer; and
a conducting coil formed on the second insulating layer.

2. The inductance device as claimed in claim 1, wherein the first insulating layer is silicon oxide.

3. The inductance device as claimed in claim 2, wherein the second insulating layer has a dielectric constant between 2 and 3.7.

4. The inductance device as claimed in claim 3, wherein the second insulating layer is a silicon or carbon based organic polymer film.

5. The inductance device as claimed in claim 1, wherein the conducting coil includes a plurality of spiral conducting lines.

6. The inductance device as claimed in claim 5, wherein the adjacent spiral conducting lines are spaced apart from a dielectric layer and are electrically connected to each other by a via hole formed in the dielectric layer.

7. The inductance device as claimed in claim 1, wherein the semiconductor substrate is defined to form a trench, and the second insulating layer is filled into the trench.

8. A process for fabricating an inductance device, comprising the following steps of:
(a) providing a semiconductor substrate;
(b) forming a first insulating layer and a second insulating layer on different surfaces of the semiconductor substrate respectively, wherein the second insulating layer has a lower dielectric constant than the first insulating layer; and
(c) forming a conducting coil on the second insulating layer.

9. The process as claimed in claim 8, wherein the first insulating layer is silicon oxide.

10. The process as claimed in claim 9, wherein the second insulating layer has a dielectric constant between 2 and 3.7.

11. The process as claimed in claim 10, wherein the second insulating layer is an silicon or carbon based organic polymer film.

12. The process as claimed in claim 10, wherein the conducting coil includes a plurality of spiral conducting lines.

13. The process as claimed in claim 8, wherein the adjacent spiral conducting lines are spaced apart from a dielectric layer and are electrically connected to each other by a via hole formed in the dielectric layer.

14. The process as claimed in claim 8, wherein step (b) includes:
forming a first insulating layer on the semiconductor substrate;
defining the first insulating layer to form an opening; and
forming the second insulating layer within the opening.

15. The process as claimed in claim 8, wherein step (b) includes:
forming a first insulating layer on the semiconductor substrate;
defining the first insulating layer to form an opening so as to expose the semiconductor substrate;
defining the exposed semiconductor substrate to form a trench along the opening; and
forming a second insulating layer within the opening and the trench.
